(19) United States
(12) Patent Application Publication
(10) Pub. No.: US 2008/0229842 A1
(43) Pub. Date: Sep. 25, 2008

(54) SUSPENSION EQUIPPED WITH VIBRATION SENSOR AND MANUFACTURING METHOD THEREOF

(75) Inventors: Shinichi Ohtsuka, Kawasaki (JP); Shinji Koganezawa, Kawasaki (JP)

Correspondence Address: GREER, BURNS & CRAIN, 300 S WACKER DR, 25TH FLOOR, CHICAGO, IL, 60606, US

(73) Assignee: FUJITSU LIMITED, Kawasaki-shi (JP)

(21) Appl. No.: 12/035,060

(22) Filed: Feb. 21, 2008

(30) Foreign Application Priority Data
Mar. 19, 2007 (JP) 2007-071279

(51) Int. Cl. G01B 7/16; H01L 41/22

(52) U.S. Cl. 73/777; 29/25.35

(57) ABSTRACT

A suspension for a hard disk drive has a vibration sensor which is impervious to influence by external noise, to obtain more stable positioning precision of the head on the suspension. The suspension has a load beam, a vibration sensor sandwiched by a first electrode and a second electrode, and a conductive wiring pattern on the load beam for electrically connecting the first electrode and the second electrode to an external detection circuit. The first electrode is sandwiched by the second electrode via the vibration sensor and a shield layer via an insulating layer. The second electrode and the shield layer are at a same potential.

The present invention relates to a suspension equipped with a vibration sensor. In particular, the present invention relates to a structure of a vibration sensor with which a suspension is equipped and a manufacturing method thereof.

### BACKGROUND OF THE INVENTION

FIG. 1 shows a perspective view of a conventional magnetic disk apparatus, and FIG. 2 shows an enlarged perspective view of an actuator shown in FIG. 1. A magnetic recording medium 2 fixed to a spindle motor 1 rotates at high speed. With this rotation, air is drawn between a head slider 3 and the magnetic recording medium 2. The head slider 3 is floated by pressurization of the air.

As shown in FIG. 2, an actuator 4 has a suspension 6 at one end of a carriage 5 and a voice coil 7 at the other end. The actuator 4 is fixed rotatably to a housing 9 (FIG. 1) by a pivot through a shaft bearing 8 and moves in an approximate radius direction of the magnetic recording medium 2. Therefore, the head slider 3 mounted to the suspension 6 moves over the magnetic recording medium 2 in the approximate radius direction. Then, a head mounted to the head slider 3 is positioned on a predetermined track to write/read information.

In recent years, with digitization and computerization, a large-capacity recording apparatus is needed. Moreover, a magnetic recording apparatus such as an HDD is rapidly developing with high density. With high density, the recording size is becoming increasingly smaller. Moreover, higher head positioning precision is demanded for the actuator.

One factor inhibiting head positioning is disk flutter. This is a phenomenon in which a stream of air generated by rotation of a recording medium causes vibration of the recording medium. The suspension fixing the head slider floating over a recording medium also vibrates together with the recording medium, affecting head positioning precision adversely.

Japanese Patent Application Laid-Open Publication No. 2003-217244 discloses a technology for decreasing disk flutter. A strain gauge for detecting displacement in an axial direction with respect to a recording medium is mounted on a suspension. Then, a correction control signal is generated from output of the strain gauge and sent to an actuator to correct a shift of the head position with respect to the track on the recording medium.

It is also publicly known that a piezoelectric sensor can be used for detection of deformation and vibration of a member. For example, Japanese Patent No. 3208386 describes a method of inhibiting resonance by detecting actuator deformation by a piezoelectric sensor and a mounting method of the piezoelectric sensor.

However, a vibration sensor used in a suspension is very highly sensitive. Thus, if external noise mainly originating from a power supply is produced, the vibration sensor senses external noise and thus will unable to correct a head position shift correctly. In view of higher densities in the future, measures taken against external noise are very important in order to obtain satisfactory head positioning precision.

Therefore, an object of the present invention is to provide a suspension equipped with a vibration sensor having a structure impervious to external noise. Another object of the present invention is to provide a method of easily manufacturing a suspension equipped with a vibration sensor having a structure impervious to external noise.

### SUMMARY OF THE INVENTION

In accordance with an aspect of an embodiment, a suspension has a load beam, a vibration sensor sandwiched by a first electrode and a second electrode, and a conductive wiring pattern on the load beam for electrically connecting the first electrode and the second electrode to an external detection circuit. The first electrode is sandwiched by the second electrode via the vibration sensor and a shield layer via an insulating layer, and the second electrode and the shield layer are at the same potential.

In addition, in accordance with another aspect of an embodiment, a method of manufacturing the suspension includes the step of arranging the vibration sensor between the first electrode and second electrode via the insulating layer on the shield layer electrically connected to the conductive wiring pattern. A first vibration sensor terminal land part is electrically connected to the conductive wiring pattern and the first electrode, and a second vibration sensor terminal land part is electrically connected to the conductive wiring pattern and shield payer and the second electrode.

### BRIEF DESCRIPTION OF THE DRAWINGS

The present invention will be explained with reference to the accompanying drawings.

FIG. 1 is a perspective view of a conventional magnetic disk apparatus;

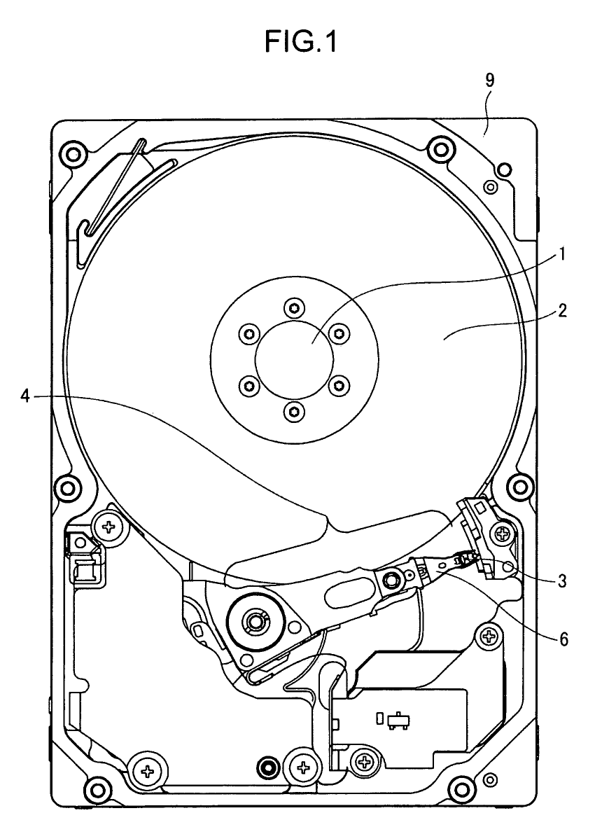

FIG. 2 is a perspective view of an actuator in FIG. 1;

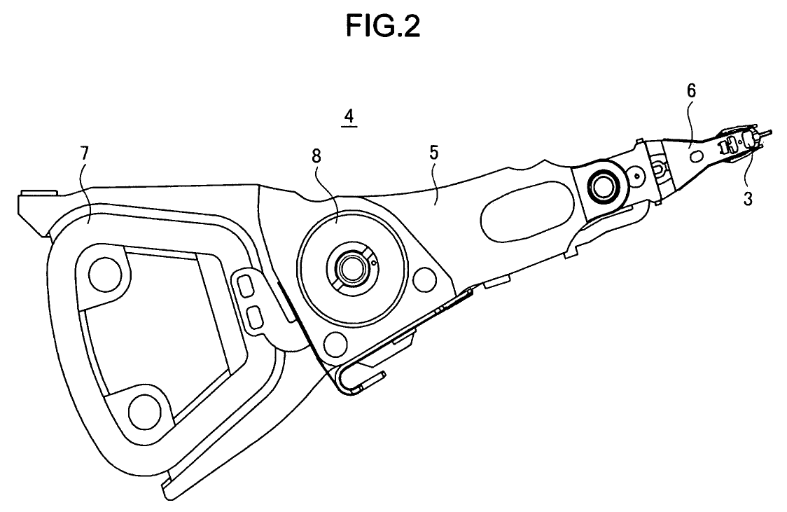

FIG. 3 is a perspective view of a suspension;

FIG. 4 is an exploded view of the suspension;

FIG. 5 is a plan view of a suspension equipped with a vibration sensor according to a first embodiment of the present invention;

FIG. 6 is a sectional view along 6-6 in FIG. 5;

FIG. 7 is a sectional view along 7-7 in FIG. 5;

FIG. 8 is a plan view of a suspension equipped with a vibration sensor according to a second embodiment of the present invention;

FIG. 9 is a sectional view along 9-9 in FIG. 8;

FIG. 10 is a perspective view of a suspension according to a third embodiment of the present invention before a vibration sensor is mounted;

FIG. 11 is a perspective view of the suspension according to the third embodiment of the present invention after the vibration sensor is mounted; and

FIG. 12 is a perspective view when viewed from an X direction in FIG. 11.

### DETAILED DESCRIPTION

Embodiments of the present invention will be described below with reference to attached drawings.

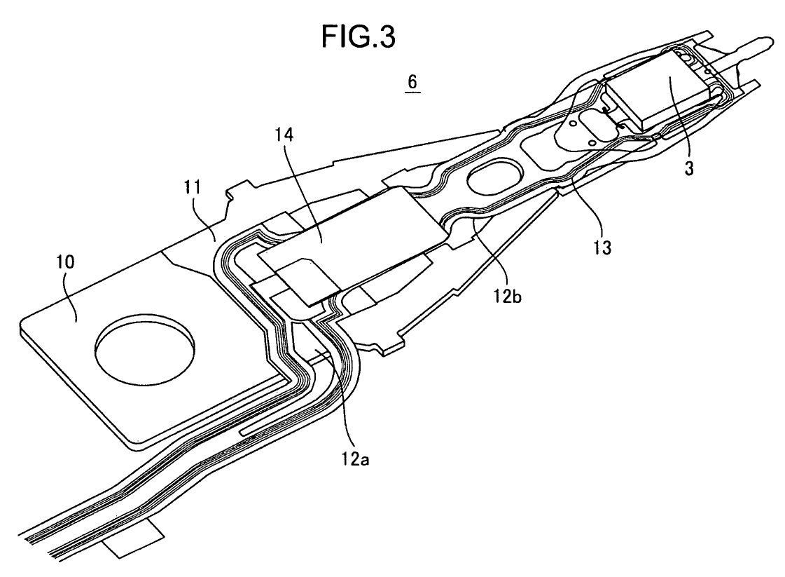

FIG. 3 shows a perspective view of a suspension of the present invention. In the suspension 6, a load beam 11 is fixed to a base plate 10 to be connected to a carriage. On the load beam 11, flexures 12a and 12b and a wiring pattern 13 are arranged in order. The head slider 3 is arranged on a portion of the flexure 12b. A vibration sensor 14 is arranged on a portion of the wiring pattern 13.

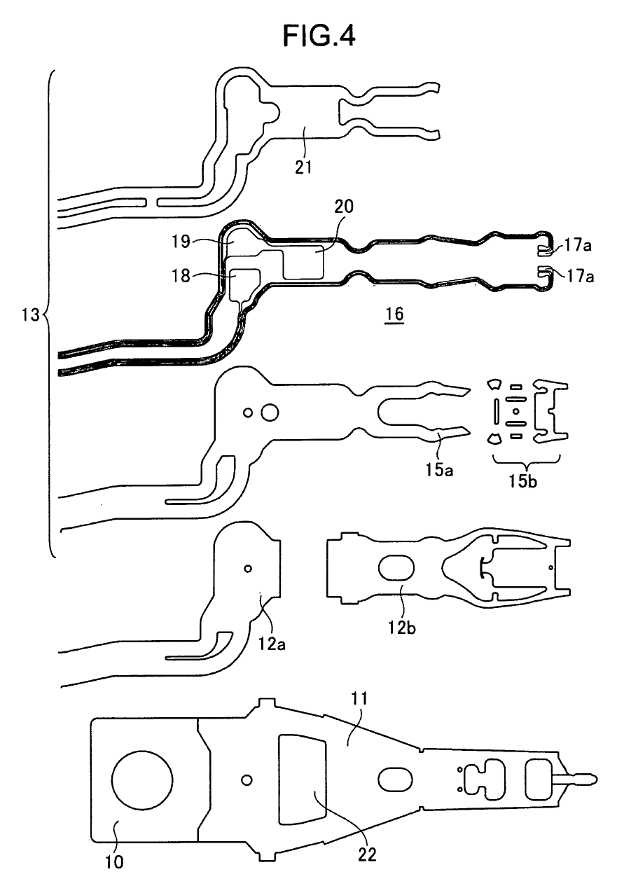

FIG. 4 shows an exploded view of the suspension of the present invention. A hollow part 22 is provided in the load beam 11 to constitute a elastic part. The flexures 12a and 12b are separated by the hollow part 22 of the load beam 11. The wiring pattern 13 is formed of insulating layers 15a and 15b, a conductive wiring pattern 16, and an insulating cover layer 21. A head terminal of the head slider 3 is electrically connected to head terminal land parts 17a and 17b formed at tip parts of the conductive wiring pattern 16 by soldering or the like. The conductive wiring pattern 16 also has a first vibration sensor terminal land part 18 and a second vibration sensor terminal land part 19 to be electrically connected to the vibration sensor formed thereon. Further, a shield layer 20 is formed as a portion for mounting the vibration sensor. The shield layer 20 and the second vibration sensor terminal land part 19 are connected. The head and vibration sensor are connected to outside circuits via the conductive wiring pattern 16. Incidentally, no cover layer is attached to the head terminal land parts 17a and 17b, the first vibration sensor terminal land part 18, and the second vibration sensor terminal land part 19, which serve as an electrical connection portion between the conductive wiring pattern 16 and vibration sensor terminal and between the head terminal and vibration sensor terminal.

In the present embodiment, the wiring pattern 13 is provided in such a way that the hollow part 22 of the suspension 6 is crossed. The vibration sensor 14 is mounted in a portion where the hollow part 22 of the suspension 6 is crossed by the wiring pattern 13. Therefore, the increase of the spring stiffness of the suspension 6 and the decrease of the vibration sensor can be suppressed. Incidentally, the vibration sensor is mounted using an adhesive or pressure sensitive adhesive tape.

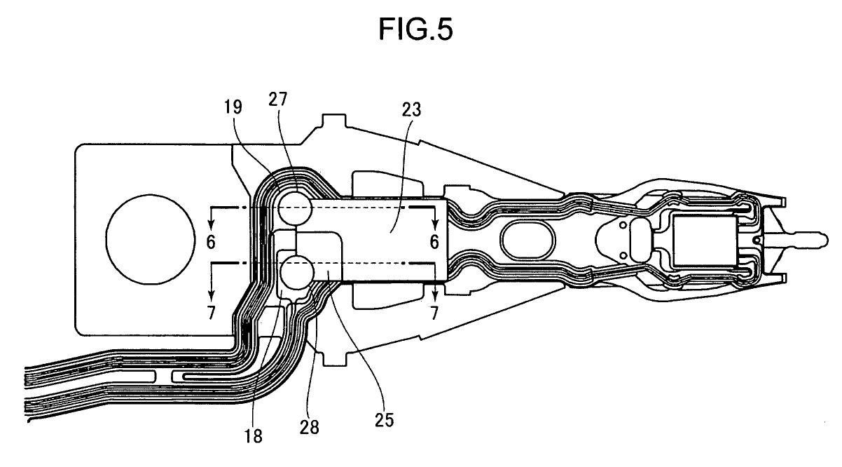

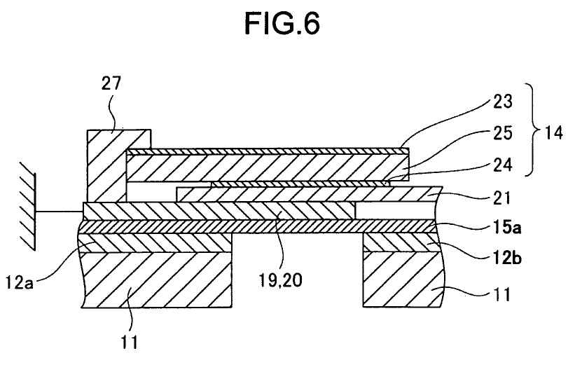

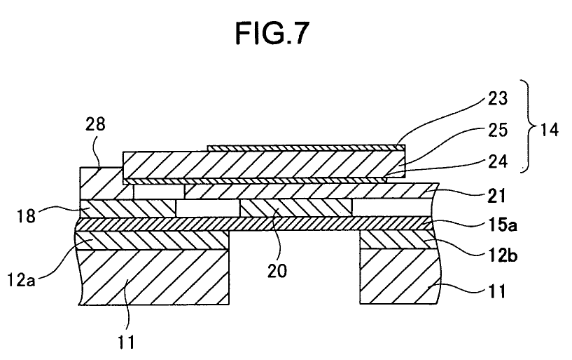

Further, a state in which the vibration sensor is mounted on the shield layer 20 will be described. FIG. 5 is a plan view of a suspension equipped with a vibration sensor according to a first embodiment of the present invention. FIG. 6 is a sectional view along 6-6 in FIG. 5. FIG. 7 is a sectional view along 7-7 in FIG. 5. As shown in FIGS. 6 and 7, an upper electrode 23 and a lower electrode 24 are formed on the upper and lower surfaces of a piezoelectric material 25 in the vibration sensor 14. The piezoelectric material is typically piezoelectric ceramic such as PZT (Pb(Zr—Ti)O3: lead-zirconate-titanate). A piezoelectric polymeric material is suitable because it is excellent in flexibility, processibility (easy to process), and impact resistance. And output sensitivity is advantageous when used with voltage amplifier circuit. The piezoelectric polymeric material includes, for example, PVDF (PolyVinyliDene Fluoride). When PVDF is used, electrodes are formed on the surface thereof by screen printing or the like.

As shown in FIG. 5, a portion of the upper electrode 23 which is connected to the second vibration sensor terminal land part 19 of the wiring pattern and a portion of the lower electrode (not shown) which is connected to the first vibration sensor terminal land part 18 of the wiring pattern are not overlapping as viewed perpendicular to the upper and lower electrode. These portions are connected by conductive adhesives 27 and 28. For example, first a vibration sensor is arranged on the shield layer 20 and, as shown in FIG. 6, the conductive adhesive 27 is arranged so that the second vibration sensor terminal land part 19 and the upper electrode 23 are connected to each other. Next, as shown in FIG. 7, the conductive adhesive 28 is arranged so that the first vibration sensor terminal land part 18 and the lower electrode 24 are connected. In this manner, a suspension according to the present invention is manufactured.

With a structure described above, the upper electrode 23 of the piezoelectric material 25, the second vibration sensor terminal land part 19, and the shield layer 20 are at the same potential. An influence of external noise can be significantly reduced by grounding the pattern wire drawn out of the second vibration sensor terminal land part 19 and selecting an electrode mounted to the suspension, that is, the lower electrode 24 as an output electrode. This is because the output electrode has a shield structure surrounded by the grounding electric potential.

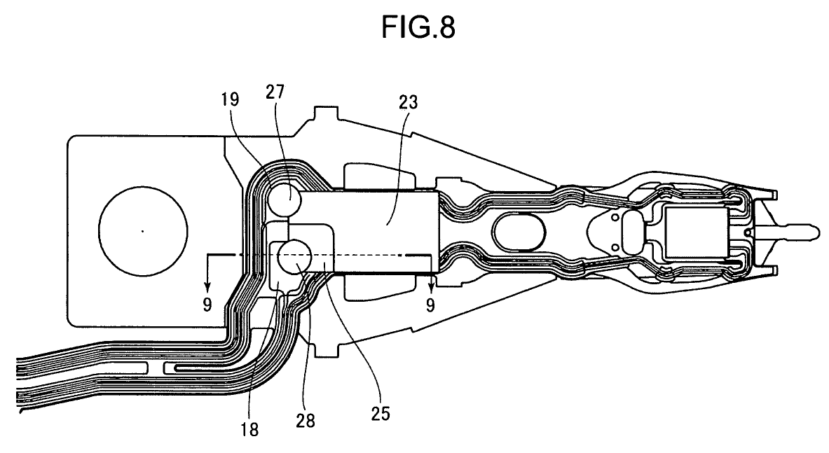

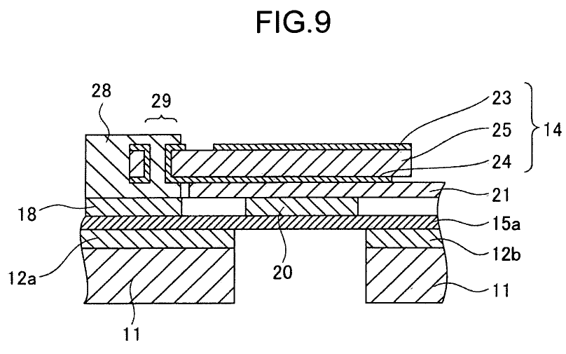

FIG. 8 shows a plan view of a suspension equipped with a vibration sensor according to a second embodiment of the present invention. The vibration sensor is arranged with a configuration similar to that of the first embodiment. Next, FIG. 9 shows a sectional view along 9-9 in FIG. 8. The sectional view is the same as that in the first embodiment except that a through hole 29 is formed in the vibration sensor 14. The through hole 29 provides a through-hole in the vibration sensor 14 and the lower electrode 24 is drawn upward to wrap the through-hole. Therefore, in work efficiency of arranging adhesive between the first vibration sensor terminal land part 18 and the lower electrode 24, efficiency can be improved while ensuring reliable electric connection even if the arranging direction of the conductive adhesive 28 is one direction from above.

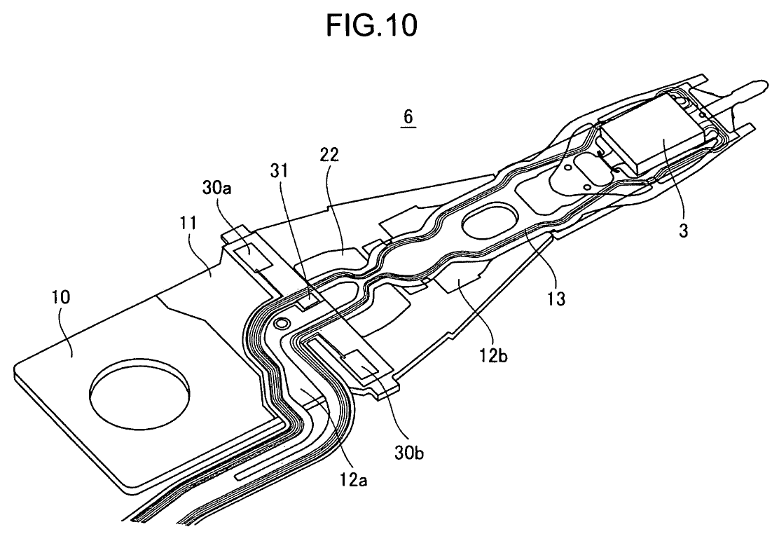

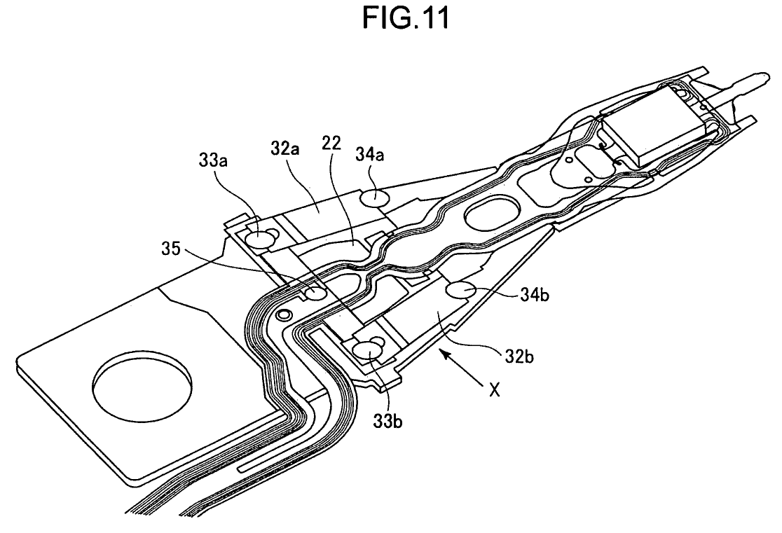

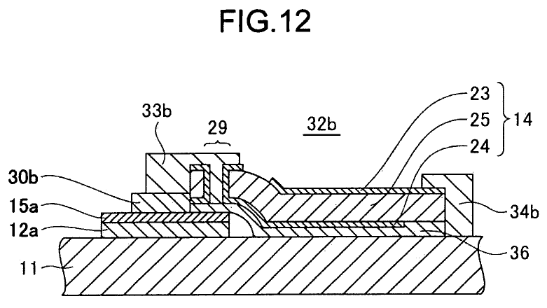

FIG. 10 shows a perspective view of a suspension according to a third embodiment of the present invention before a vibration sensor is mounted. In the third embodiment, the shield layer used in the first and second embodiments is not provided. On the other hand, a flexure connection land part 31 is arranged on the insulating layer. Also in the third embodiment, vibration sensor terminal land parts 30a and 30b are arranged on an insulating layer positioned differently from the first and second embodiments. Next, FIG. 11 shows a perspective view of the suspension according to the third embodiment of the present invention after the vibration sensor is mounted. A two-part vibration sensor 32a, 32b is fixed to both ends of the hollow part 22 of the load beam 11 by a non-conductive adhesive 36 (FIG. 12).

Here, FIG. 12 shows a perspective view when viewed from an X direction in FIG. 11. The lower electrode 24 of vibration sensors 32b (and 32a) and the vibration sensor terminal land parts 30b (and 30a) are electrically connected by conductive adhesives 33b (and 33a). Also, the upper electrode 23 of the vibration sensors 32b (and 32a) and the load beam 11 are electrically connected by conductive adhesives 34b (and 34a). Further, the flexure connection land part 31 and the flexure 12 are electrically connected by a conductive adhesive 35.

The upper electrode 23 of the vibration sensor 32, the load beam 11, and the flexure 12 are at the same potential. A pattern wire drawn out of the flexure connection land part 31 is grounded and the lower electrode 24 mounted on the suspension is selected as an output electrode. The output electrode has a shield structure surrounded by the grounding electric potential, leading to significant reduction of an influence of external noise.

According to a suspension in the present embodiment, a suspension equipped with a vibration sensor impervious to an influence of external noise can be provided. Therefore, stable positioning precision of a head can be obtained. Also, according to a manufacturing method of a suspension in the present embodiment, such a suspension can be manufactured easily.

What is claimed is:

1. A suspension comprising;
a load beam,
a vibration sensor sandwiched by a first electrode and a second electrode, and
a conductive wiring pattern on said load beam for electrically connecting said first electrode and said second electrode to an external detection circuit, wherein
said first electrode is sandwiched by said second electrode via said vibration sensor and a shield layer via an insulating layer, and
said second electrode and said shield layer are at a same potential.

2. The suspension according to claim 1, wherein said shield layer is said load beam.

3. The suspension according to claim 2, wherein said second electrode and said shield layer are grounded.

4. The suspension according to claim 1, wherein said second electrode and said shield layer are grounded.

5. The suspension according to claim 1, wherein said vibration sensor is made of a piezoelectric material.

6. The suspension according to claim 2, wherein said vibration sensor is made of a piezoelectric material.

7. The suspension according to claim 3, wherein said vibration sensor is made of a piezoelectric material.

8. The suspension according to claim 4, wherein said vibration sensor is made of a piezoelectric material.

9. The suspension according to claim 5, wherein said piezoelectric material is a piezoelectric polymeric material.

10. The suspension according to claim 6, wherein said piezoelectric material is a piezoelectric polymeric material.

11. The suspension according to claim 7, wherein said piezoelectric material is a piezoelectric polymeric material.

12. The suspension according to claim 8, wherein said piezoelectric material is a piezoelectric polymeric material.

13. A method of manufacturing a suspension having a vibration sensor sandwiched by a first electrode and a second electrode and a conductive wiring pattern for electrically connecting said first electrode and said second electrode to an external detection circuit, wherein said first electrode is sandwiched by said second electrode via said vibration sensor and a shield layer via an insulating layer and said second electrode and said shield layer are at a same potential, the method comprising the steps of:
arranging said vibration sensor between said first electrode and second electrode via said insulating layer on said shield layer electrically connected to said conductive wiring pattern;
electrically connecting a first vibration sensor terminal land part to said conductive wiring pattern and said first electrode; and
electrically connecting a second vibration sensor terminal land part to said conductive wiring pattern and shield layer and said second electrode.

14. The method of manufacturing a suspension according to claim 13, wherein said first vibration sensor terminal land part and first electrode and said second vibration sensor terminal land part and second electrode are electrically connected by a conductive adhesive.
